(19) United States
(12) Patent Application Publication
(10) Pub. No.: US 2024/0306518 A1
(43) Pub. Date: Sep. 12, 2024

(54) STRUCTURE, QUANTUM BIT, AND METHOD FOR MANUFACTURING STRUCTURE

(71) Applicant: Fujitsu Limited, Kawasaki-shi (JP)

(72) Inventor: Junichi YAMAGUCHI, Atsugi (JP)

(73) Assignee: Fujitsu Limited, Kawasaki-shi (JP)

(21) Appl. No.: 18/660,129

(22) Filed: May 9, 2024

Related U.S. Application Data
(63) Continuation of application No. PCT/JP2021/043410, filed on Nov. 26, 2021.

(51) Int. Cl. H10N 60/85; H10N 60/01; H10N 60/12

(52) U.S. Cl. CPC H10N 60/85; H10N 60/0156; H10N 60/12

(57) ABSTRACT

A structure includes: a base material; a first layer provided over the base material; and a second layer provided over the first layer. The first layer is a Te layer, and the second layer includes a transition metal ditelluride layer.

### CROSS-REFERENCE TO RELATED APPLICATION

This application is a continuation application of International Application PCT/JP2021/043410 filed on Nov. 26, 2021, and designated the U.S., the entire contents of which are incorporated herein by reference.

### FIELD

The present disclosure discussed herein is related to a structure, a quantum bit, a quantum operation device, and a method for manufacturing a structure.

### BACKGROUND

A quantum operation device using Majorana particles has been studied. As a structure for generating the Majorana particle, a structure in which a two-dimensional topological insulator and an s-wave superconductor are combined has been proposed. As the two-dimensional topological insulator, a single-layer film of WTe₂ that is a layered material of transition metal ditelluride is used. Furthermore, a higher-order topological insulator layer including a multilayer WTe₂ has been studied.

U.S. Patent Application Publication No. 2019/0131129, Japanese Laid-open Patent Publication No. 2018-9201, N. Read and D. Green, Phys. Rev. B 61, 10267 (2000), V. Mourik et al., Science 336, 25 (2012), J. Alicea, Rep. Prog. Phys. 75, 076501 (2012), S. Wu et al., Science 359, 76 (2018), and Y. B. Choi et al., Nat. Mater 19, 974 (2020) are disclosed as related art.

### SUMMARY

According to an aspect of the embodiments, a structure includes: a base material; a first layer provided over the base material; and a second layer provided over the first layer. The first layer is a Te layer, and the second layer includes a transition metal ditelluride layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a structure according to a first embodiment;

FIG. 2 is a diagram illustrating a result of Raman spectrometry related to the first embodiment;

FIG. 3 is a cross-sectional view illustrating a structure according to a second embodiment;

FIG. 4 is a diagram illustrating a result of Raman spectrometry related to the second embodiment;

FIG. 5 is a cross-sectional view illustrating a structure according to a third embodiment;

FIG. 6 is a diagram illustrating a result of Raman spectrometry related to the third embodiment;

FIG. 7 is a top view illustrating a quantum bit according to a fourth embodiment;

FIG. 8 is a cross-sectional view (part 1) illustrating the quantum bit according to the fourth embodiment;

FIG. 9 is a cross-sectional view (part 2) illustrating the quantum bit according to the fourth embodiment;

FIG. 10 is a perspective view illustrating a higher-order topological insulator layer;

FIG. 11 is a top view (part 1) illustrating a method for manufacturing the quantum bit according to the fourth embodiment;

FIG. 12 is a top view (part 2) illustrating the method for manufacturing the quantum bit according to the fourth embodiment;

FIG. 13 is a top view (part 3) illustrating the method for manufacturing the quantum bit according to the fourth embodiment;

FIG. 14 is a top view (part 4) illustrating the method for manufacturing the quantum bit according to the fourth embodiment;

FIG. 15 is a top view (part 5) illustrating the method for manufacturing the quantum bit according to the fourth embodiment;

FIG. 16 is a top view (part 6) illustrating the method for manufacturing the quantum bit according to the fourth embodiment;

FIG. 17 is a cross-sectional view (part 1) illustrating the method for manufacturing the quantum bit according to the fourth embodiment;

FIG. 18 is a cross-sectional view (part 2) illustrating the method for manufacturing the quantum bit according to the fourth embodiment;

FIG. 19 is a cross-sectional view (part 3) illustrating the method for manufacturing the quantum bit according to the fourth embodiment;

FIG. 20 is a cross-sectional view (part 4) illustrating the method for manufacturing the quantum bit according to the fourth embodiment;

FIG. 21 is a cross-sectional view (part 5) illustrating the method for manufacturing the quantum bit according to the fourth embodiment;

FIG. 22 is a cross-sectional view (part 6) illustrating the method for manufacturing the quantum bit according to the fourth embodiment; and

FIG. 23 is a diagram illustrating a quantum operation device according to a fifth embodiment.

### DESCRIPTION OF EMBODIMENTS

Although proposals based on the theory have been made in the past, it is not easy to stably obtain a transition metal ditelluride layer such as WTe₂ with excellent crystallinity.

An object of the present disclosure is to provide a structure that can obtain excellent crystallinity in a transition metal ditelluride layer, a quantum bit, a quantum operation device, a method for manufacturing the structure.

Hereinafter, embodiments of the present disclosure will be specifically described with reference to the attached drawings. Note that, in the present specification and drawings, components having substantially the same functional configuration are denoted with the same reference numeral, and redundant descriptions may be omitted. In the present disclosure, it is assumed that an X1-X2 direction, a Y1-Y2 direction, and a Z1-Z2 direction are directions orthogonal to each other. A plane including the X1-X2 direction and the Y1-Y2 direction is described as an XY plane, a plane including the Y1-Y2 direction and the Z1-Z2 direction is described as a YZ plane, and a plane including the Z1-Z2 direction and the X1-X2 direction is described as a ZX plane. Note that, for convenience, the Z1-Z2 direction is set as a vertical direction, and a Z1 side is set as an upper side, and a Z2 side is set as a lower side. Furthermore, a planar view refers to viewing an object from the Z1 side, and a planar shape refers to a shape of the object viewed from the Z1 side.

### First Embodiment

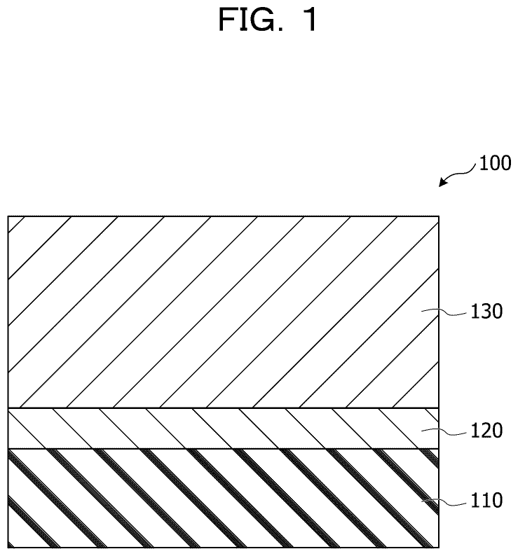

First, a first embodiment will be described. The first embodiment relates to a structure. FIG. 1 is a cross-sectional view illustrating the structure according to the first embodiment.

A structure 100 according to the first embodiment includes a substrate 110, a first layer 120, and a second layer 130. The first layer 120 is formed on the substrate 110. The second layer 130 is formed on the first layer 120.

The substrate 110 is, for example, a single crystal substrate of which a Miller index of a surface is (100). A material of the substrate 110 is, for example, MgO. In the first embodiment, the substrate 110 is an example of a base material.

The first layer 120 is a Te layer that does not include W. A thickness of the first layer 120 is, for example, 1 nm to 20 nm.

The second layer 130 is, for example, a multilayer WTe₂. For example, the multilayer WTe₂ includes 5 layers to 100 layers, and more preferably, 10 layers to 50 layers of WTe₂ that is a two-dimensional material. Since a thickness of a single layer WTe₂ is 0.7 nm, in a case where the second layer 130 includes 70 layers of WTe₂, a thickness of the second layer 130 is about 50 nm.

Next, a method for manufacturing the structure 100 according to the first embodiment will be described. Here, description will be made as assuming that a MgO single crystal substrate of which the Miller index is (100) is used as the substrate 110, the Te layer is formed as the first layer 120, and the multilayer WTe₂ is formed as the second layer 130.

First, the substrate 110 is prepared, and annealing processing on the substrate 110 is executed for 3 hours to 4 hours at about 1200° C., under an oxygen atmosphere at atmospheric pressure. Next, the substrate 110 is immersed in methanol for 20 minutes to 30 minutes, and rinse processing is executed with ultrapure water. By these processing, it is possible to improve flatness of the surface of the substrate 110.

Next, the first layer 120 is formed on the substrate 110, and the second layer 130 is formed on the first layer 120. The first layer 120 and the second layer 130 can be epitaxially grown in situ in the same vacuum chamber, for example, by pulse laser deposition (PLD). A basic vacuum at the time when the first layer 120 and the second layer 130 are formed is set to, for example, equal to or less than 5×10⁻⁶ Pa. When the first layer 120 and the second layer 130 are formed by the PLD method, a KrF excimer laser (λ=248 nm) light source can be used as a laser light source. Note that the method for forming the first layer 120 and the second layer 130 is not limited to the PLD method. For example, the first layer 120 and the second layer 130 may be formed by a sputtering method, and the first layer 120 may be formed by a vapor deposition method, and the second layer 130 may be formed by a co-vapor deposition method. In this way, the first layer 120 and the second layer 130 can be formed by a physical vapor deposition method in a vacuum in-situ process.

When the first layer 120 is formed, for example, a Te pure metal target can be used as a target. When the first layer 120 is formed, for example, a temperature of the substrate 110 is held at about 200° C., a laser energy density is set to 1.0 J/cm², an irradiation frequency is set to 1 Hz, a distance between the substrate 110 and the target is set to about 5 cm, and a film formation rate is set to 1.0 nm/minute.

When the multilayer WTe₂ is formed as the second layer 130 by the PLD method, for example, a WTe₂ sintered body target can be used as the target. When the second layer 130 is formed, for example, the temperature of the substrate 110 is held at 325° C., the laser energy density is set to 1.0 J/cm², the irradiation frequency is set to 10 Hz, the distance between the substrate 110 and the target is set to about 5 cm, and the film formation rate is set to 1.0 nm/minute. The second layer 130 (multilayer WTe₂) is oriented in a c-axis direction on the first layer 120, and a crystal structure of the second layer 130 indicates a T_{d} structure.

In this way, the structure 100 according to the first embodiment can be manufactured.

In the structure 100, the first layer 120 is formed between the substrate 110 and the second layer 130. Although a lattice mismatch between MgO of which the Miller index of the surface is (100) and WTe₂ is 33%, the first layer 120 functions as a seed layer when the second layer 130 is formed. Therefore, it is possible to obtain excellent crystallinity for the second layer 130.

Note that, after the multilayer WTe₂ is formed, it is preferable to perform post annealing for 30 minutes to 1 hour at about 300° C. This is because the crystallinity of the multilayer WTe₂ is improved.

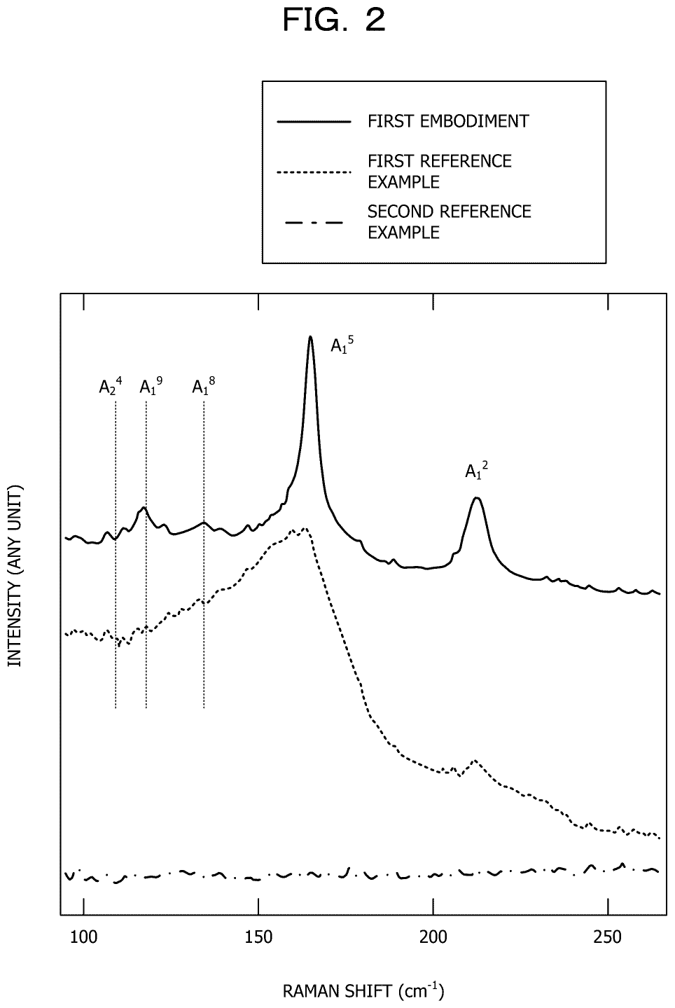

Next, a result of Raman spectrometry related to the first embodiment performed by the present inventor will be described. In this measurement, a sample was created according to the first embodiment, and the Raman spectrometry was performed on the sample. Note that the thickness of the first layer 120 was set to 10 nm, and the thickness of the second layer 130 was set to 50 nm. Furthermore, for reference, a sample (first reference example) in which the second layer 130 is formed on the substrate 110 without forming the first layer 120 and a sample (second reference example) including only the substrate 110 were created, and the Raman spectrometry was performed on these samples. FIG. 2 is a diagram illustrating the result of the Raman spectrometry related to the first embodiment.

As illustrated in FIG. 2, in the sample in the first embodiment, sharp peaks of lattice vibration modes (A₁², A₁⁵, A₁⁸, A₁⁹, and A₂⁴) derived from WTe₂ can be confirmed. In the sample in the first reference example, only broad peaks of the A₁² mode and the A₁⁵ mode are observed. From these results, it can be confirmed that the crystallinity of the second layer 130 is improved by providing the first layer 120.

Note that the material of the substrate 110 may be mica, sapphire, SiC, or the like.

### Second Embodiment

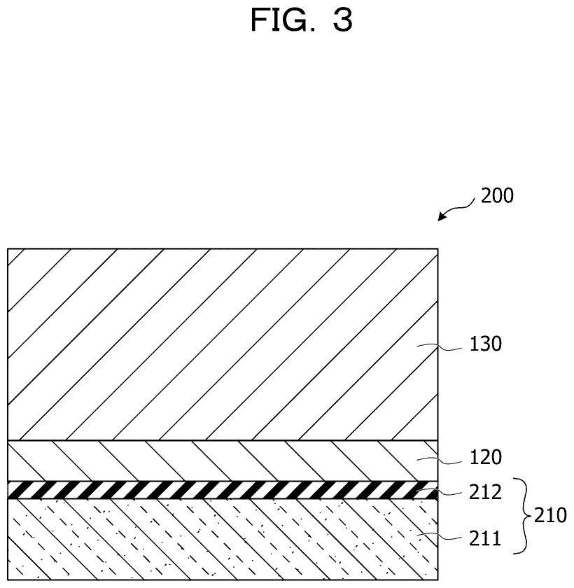

Next, a second embodiment will be described. The second embodiment is different from the first embodiment mainly in a structure of a substrate. FIG. 3 is a cross-sectional view illustrating a structure according to the second embodiment.

A structure 200 according to the second embodiment includes a substrate 210, a first layer 120, and a second layer 130. The first layer 120 is formed on the substrate 210. The second layer 130 is formed on the first layer 120.

The substrate 210 includes a Si substrate 211 and a SiO₂ film 212 formed on the Si substrate 211. The SiO₂ film 212 is formed, for example, by thermal oxidation of the Si substrate 211. For example, the substrate 210 is a Si substrate with a thermally oxidized film. The first layer 120 is provided on the SiO₂ film 212. In the second embodiment, the substrate 210 is an example of a base material.

Other components are similar to those of the first embodiment.

Next, a method for manufacturing the structure 200 according to the second embodiment will be described.

First, the substrate 210 is prepared, and annealing processing on the substrate 210 is executed for 15 minutes at about 800° C., under an oxygen atmosphere at atmospheric pressure. By the annealing processing, it is possible to remove an organic system fouling on a surface of the SiO₂ film 212.

Next, the first layer 120 is formed on the substrate 210, and the second layer 130 is formed on the first layer 120. The first layer 120 and the second layer 130 can be formed by a method similar to that in the first embodiment.

In this way, the structure 200 according to the second embodiment can be manufactured.

In the structure 200, the first layer 120 is formed between the substrate 210 and the second layer 130. Although the SiO₂ film 212 existing on the surface of the substrate 210 is amorphous, the first layer 120 functions as a seed layer when the second layer 130 is formed. Therefore, it is possible to obtain excellent crystallinity for the second layer 130.

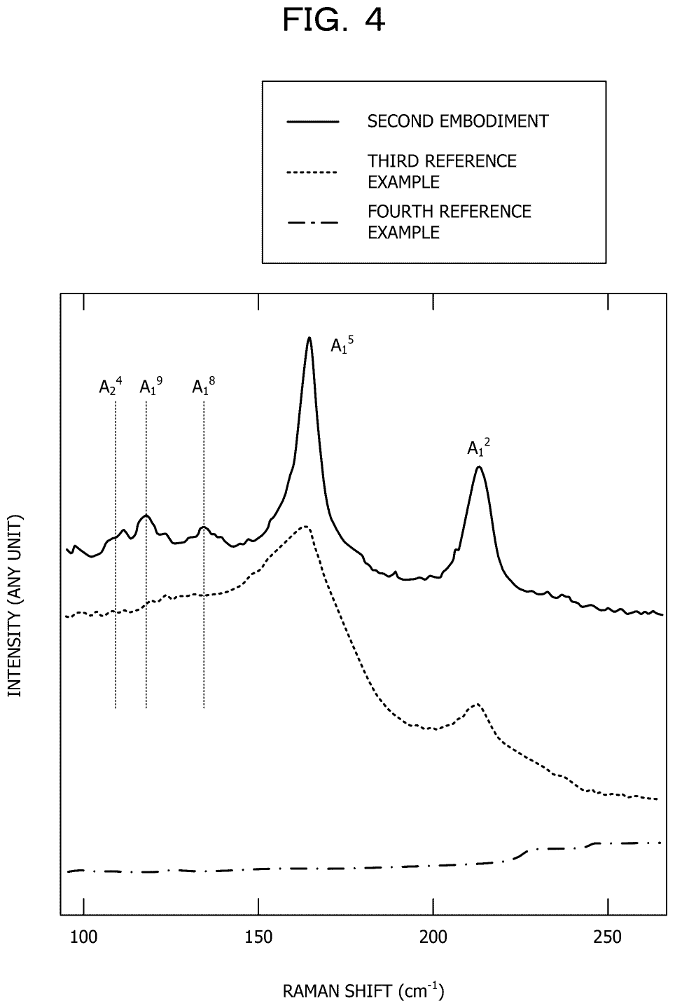

Next, a result of Raman spectrometry related to the second embodiment performed by the present inventor will be described. In this measurement, a sample was created according to the second embodiment, and the Raman spectrometry was performed on the sample. Note that the thickness of the first layer 120 was set to 10 nm, and the thickness of the second layer 130 was set to 50 nm. Furthermore, for reference, a sample (third reference example) in which the second layer 130 is formed on the substrate 210 without forming the first layer 120 and a sample (fourth reference example) including only the substrate 210 were created, and the Raman spectrometry was performed on these samples. FIG. 4 is a diagram illustrating the result of the Raman spectrometry related to the second embodiment.

As illustrated in FIG. 4, in the sample in the second embodiment, sharp peaks of lattice vibration modes (A₁², A₁⁵, A₁⁸, A₁⁹, and A₂⁴) derived from WTe₂ can be confirmed. In the sample in the third reference example, only broad peaks of the A₁² mode and the A₁⁵ mode are observed. From these results, it can be confirmed that the crystallinity of the second layer 130 is improved by providing the first layer 120.

### Third Embodiment

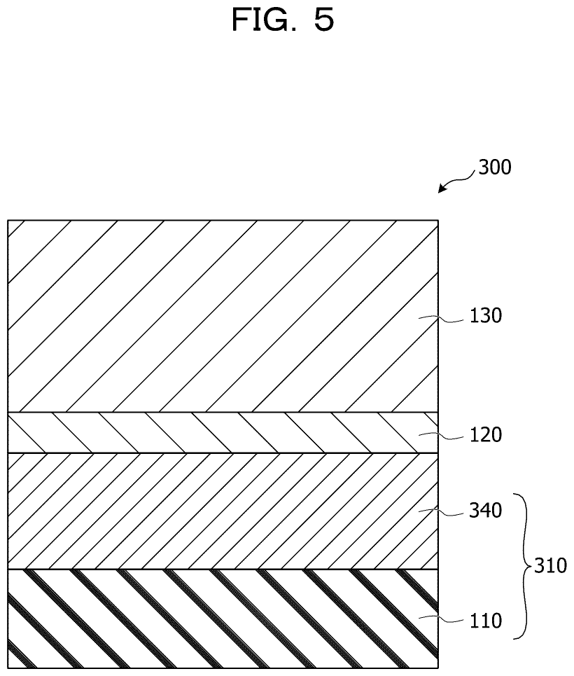

Next, a third embodiment will be described. The third embodiment is different from the first embodiment in that an s-wave superconductor layer mainly. FIG. 5 is a cross-sectional view illustrating a structure according to the third embodiment.

A structure 300 according to the third embodiment includes a substrate 110, an s-wave superconductor layer 340, a first layer 120, and a second layer 130. The s-wave superconductor layer 340 is formed on the substrate 110. The first layer 120 is formed on the s-wave superconductor layer 340. The second layer 130 is formed on the first layer 120.

The s-wave superconductor layer 340 is, for example, an Nb layer of which a Miller index of a surface is (110). A thickness of the s-wave superconductor layer 340 is, for example, about 100 nm to 200 nm. In the third embodiment, a laminated body 310 of the substrate 110 and the s-wave superconductor layer 340 is an example of a base material.

Other components are similar to those of the first embodiment.

Next, a method for manufacturing the structure 300 according to the third embodiment will be described.

First, the substrate 110 is prepared, and annealing processing and rinse processing are executed, as in the first embodiment.

Next, the s-wave superconductor layer 340 is formed on the substrate 110, the first layer 120 is formed on the s-wave superconductor layer 340, and the second layer 130 is formed on the first layer 120. Hereinafter, description will be made as assuming that an Nb layer is formed as the s-wave superconductor layer 340. The s-wave superconductor layer 340, the first layer 120, and the second layer 130 can be epitaxially grown in situ, in the same vacuum chamber, for example, by the PLD method. A basic vacuum at the time when the s-wave superconductor layer 340, the first layer 120, and the second layer 130 are formed is set to, for example, equal to or less than 5×10⁻⁶ Pa. When the s-wave superconductor layer 340, the first layer 120, and the second layer 130 are formed by the PLD method, a KrF excimer laser (λ=248 nm) light source can be used as a laser light source. Note that a method for forming the s-wave superconductor layer 340, the first layer 120, and the second layer 130 is not limited to the PLD method. For example, the s-wave superconductor layer 340, the first layer 120, and the second layer 130 may be formed by a sputtering method, and the s-wave superconductor layer 340 and the first layer 120 may be formed by a vapor deposition method, and the second layer 130 may be formed by a co-vapor deposition method.

In a case where the Nb layer is formed as the s-wave superconductor layer 340 by the PLD method, for example, an Nb pure metal target can be used as a target. When the s-wave superconductor layer 340 is formed, for example, a temperature of the substrate 110 is held at about 400° C., a laser energy density is set to 2.0 J/cm², an irradiation frequency is set to 10 Hz, a distance between the substrate 110 and the target is set to about 5 cm, and a film formation rate is set to 1.0 nm/minute. On the substrate 110 held at about 400° C., the Nb layer is epitaxially grown while being oriented in a direction.

Next, the first layer 120 is formed on the s-wave superconductor layer 340, and the second layer 130 is formed on the first layer 120. The first layer 120 and the second layer 130 can be formed by a method similar to that in the first embodiment. The s-wave superconductor layer 340, the first layer 120, and the second layer 130 can be formed by a physical vapor deposition method in a vacuum in-situ process.

In this way, the structure 300 according to the third embodiment can be manufactured.

In the structure 300, the first layer 120 is formed between the s-wave superconductor layer 340 and the second layer 130. Although a lattice mismatch between Nb of which the Miller index of the surface is (110) and WTe₂ is 25%, the first layer 120 functions as a seed layer when the second layer 130 is formed. Therefore, it is possible to obtain excellent crystallinity for the second layer 130.

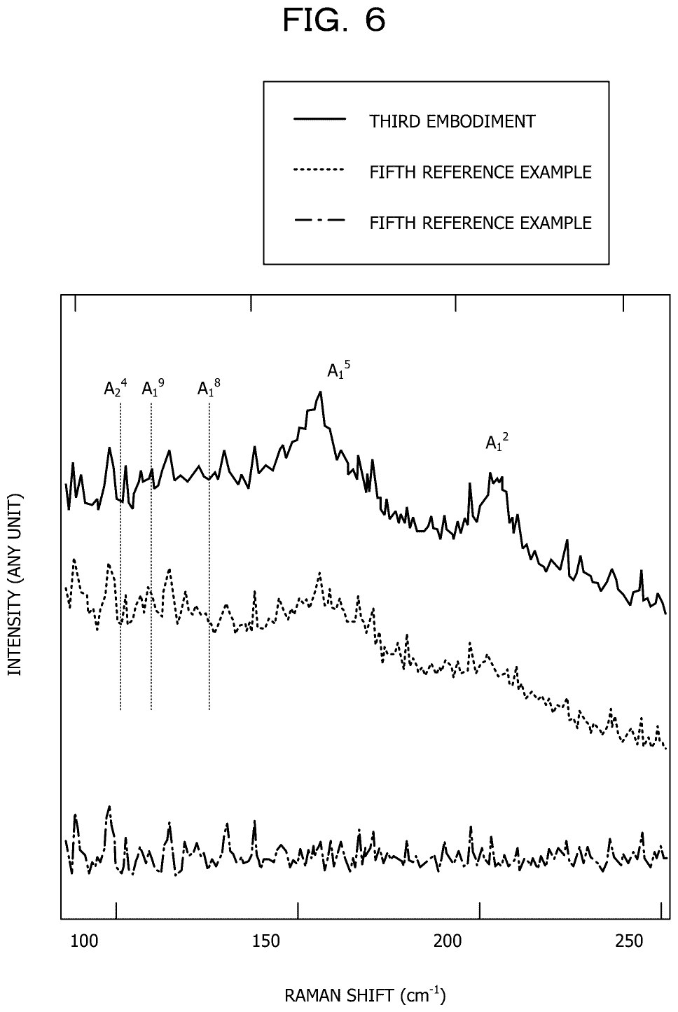

Next, a result of Raman spectrometry related to the third embodiment performed by the present inventor will be described. In this measurement, a sample was created according to the third embodiment, and the Raman spectrometry was performed on the sample. Note that a thickness of the s-wave superconductor layer 340 was set to 150 nm, the thickness of the first layer 120 was set to 5 nm, and the thickness of the second layer 130 was set to 20 nm. Furthermore, for reference, a sample (fifth reference example) in which the second layer 130 is formed on the s-wave superconductor layer 340 without forming the first layer 120 and a sample (sixth reference example) in which only the s-wave superconductor layer 340 is formed on the substrate 110 were created, and the Raman spectrometry was performed on these samples. FIG. 6 is a diagram illustrating the result of the Raman spectrometry related to the third embodiment.

As illustrated in FIG. 6, in the sample in the third embodiment, sharp peaks of lattice vibration modes (A₁², A₁⁵, A₁⁸, A₁⁹, and A₂⁴) derived from WTe₂ can be confirmed. In the sample in the fifth reference example, only broad peaks of the A₁² mode and the A₁⁵ mode are observed. From these results, it can be confirmed that the crystallinity of the second layer 130 is improved by providing the first layer 120.

In the present disclosure, a material of a layered transition metal ditelluride layer included in the second layer is not limited to WTe₂. The transition metal ditelluride layer may include Mo, Nb, W, Ta, Ti, Zr, Fe, Pd, Ir, or Pt, or any combination thereof as a transition metal. The layered transition metal ditelluride layer included in the second layer may be a single layer.

In the present disclosure, the thickness of the first layer is preferably 1 nm to 20 nm. When the thickness of the first layer is less than 1 nm, there is a possibility that it is difficult to obtain excellent crystallinity for the second layer. Furthermore, when the thickness of the first layer is more than 20 nm, there is a possibility that an electrical property of the first layer changes. Moreover, as in the third embodiment, in a case where the first layer is provided between the s-wave superconductor layer and the second layer, when the thickness of the first layer is excessive, there is a possibility that a proximity effect of superconduction is lowered. The thickness of the first layer is preferably 2 nm to 15 nm, and more preferably, is 3 nm to 10 nm.

### Fourth Embodiment

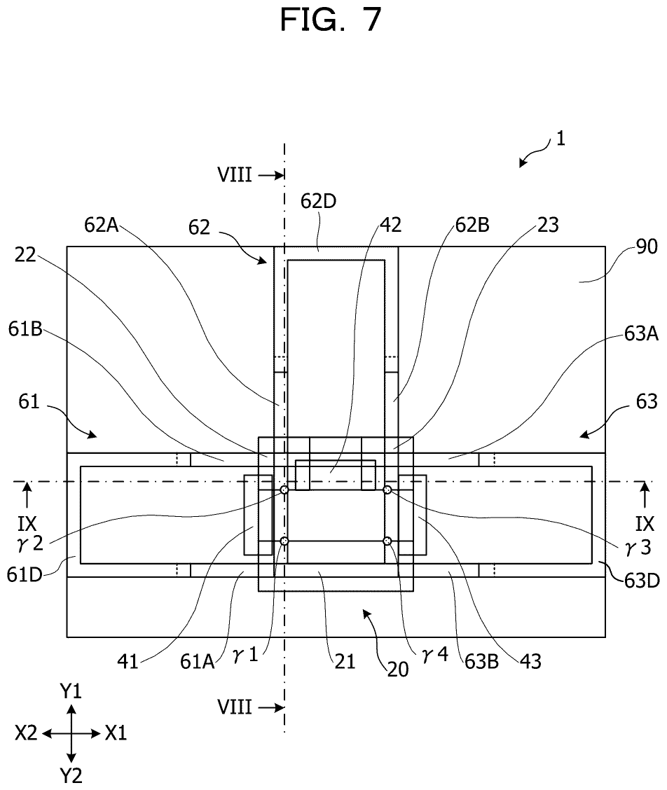

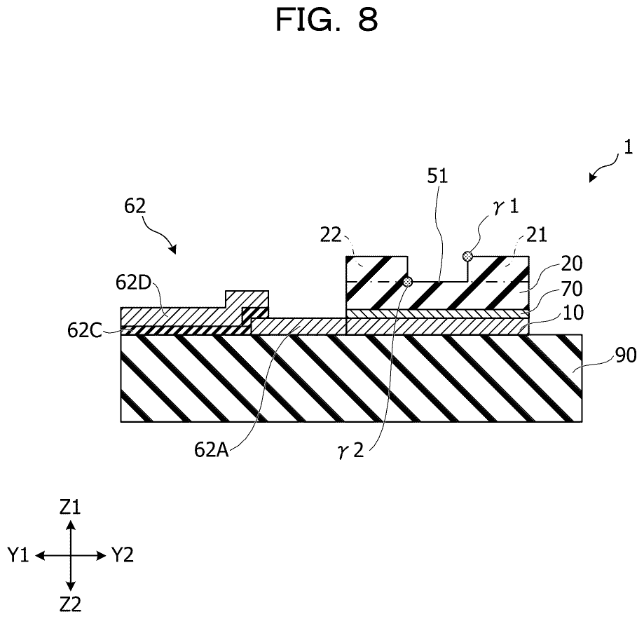

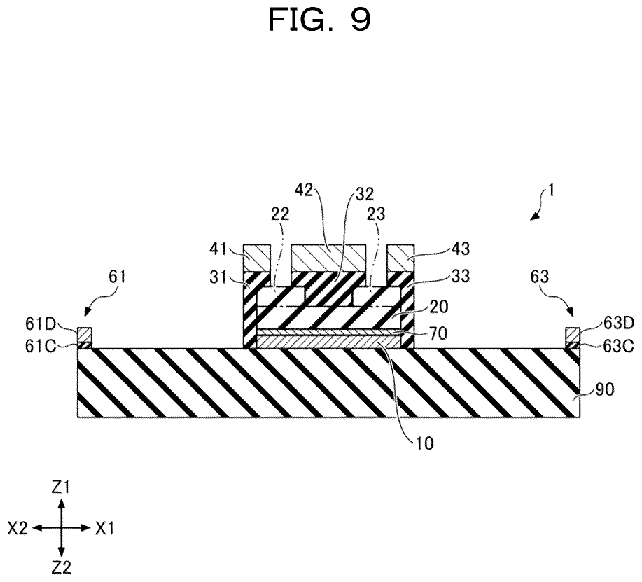

Next, a fourth embodiment will be described. The fourth embodiment relates to a quantum bit. The quantum bit according to the fourth embodiment is used for a quantum operation device, for example, a quantum computer or the like. FIG. 7 is a top view illustrating the quantum bit according to the fourth embodiment. FIGS. 8 and 9 are cross-sectional views illustrating the quantum bit according to the fourth embodiment. FIG. 8 corresponds to a cross-sectional view taken along a VIII-VIII line in FIG. 7. FIG. 9 corresponds to a cross-sectional view taken along a IX-IX line in FIG. 7.

A quantum bit 1 according to the fourth embodiment includes a substrate 90, an s-wave superconductor layer 10, a Te layer 70, a higher-order topological insulator layer 20, a first ferromagnetic insulator layer 31, a second ferromagnetic insulator layer 32, and a third ferromagnetic insulator layer 33. The quantum bit 1 further includes a first gate electrode 41, a second gate electrode 42, a third gate electrode 43, a first superconducting quantum interference device (SQUID) 61, a second SQUID 62, and a third SQUID 63.

The substrate 90 is, for example, a single crystal substrate of which a Miller index of a surface is (100). As a material of the substrate 90, MgO, mica, sapphire, and SiC are exemplified. The substrate 90 may be a Si substrate with a thermally oxidized film.

The s-wave superconductor layer 10 is provided on a part of the surface of the substrate 90. The s-wave superconductor layer 10 is, for example, an Nb layer of which the Miller index of the surface is (110). A thickness of the s-wave superconductor layer 10 is, for example, about 100 nm to 200 nm. A planar shape of the s-wave superconductor layer 10 is a rectangle having two sides parallel to the X1-X2 direction and two sides parallel to the Y1-Y2 direction.

The Te layer 70 is provided on the s-wave superconductor layer 10. A thickness of the Te layer 70 is preferably 1 nm to 20 nm, more preferably, 2 nm to 15 nm, and further more preferably, 3 nm to 10 nm. The thickness of the Te layer 70 is, for example, 5 nm.

The higher-order topological insulator layer 20 is provided on the Te layer 70. The higher-order topological insulator layer 20 is, for example, a multilayer WTe₂. For example, the multilayer WTe₂ includes 5 layers to 100 layers, and more preferably, 10 layers to 50 layers of WTe₂ that is a two-dimensional material. A thickness of the higher-order topological insulator layer 20 is, for example, 20 nm.

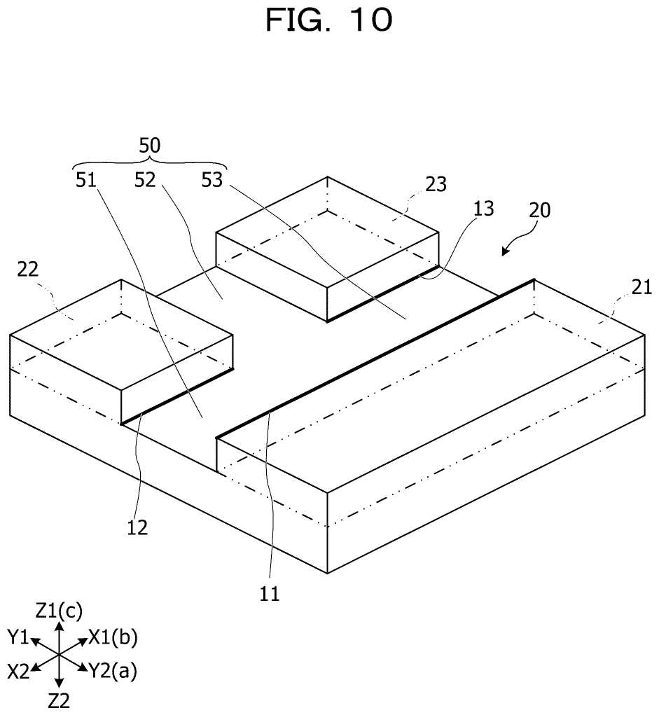

FIG. 10 is a perspective view illustrating the higher-order topological insulator layer 20. A shape of the higher-order topological insulator layer 20 is a substantially a rectangular parallelepiped. An a-axis direction of the higher-order topological insulator layer 20 is parallel to the Y1-Y2 direction, a b-axis direction is parallel to the X1-X2 direction, and a c-axis direction is parallel to the Z1-Z2 direction. A Miller index of a top surface of the higher-order topological insulator layer 20 is (001), a Miller index of a side surface on the Y2 side is (100), and a Miller index of a side surface on the X2 side is (010).

In the surface of the higher-order topological insulator layer 20, a groove 50 having a T-shape in planar view is formed. The groove 50 includes a first groove 51, a second groove 52, and a third groove 53. For example, a width of each of the first groove 51, the second groove 52, and the third groove 53 is 20 nm, and a depth of each of the first groove 51, the second groove 52, and the third groove 53 is 10 nm. The first groove 51 and the third groove 53 extend in parallel to the X1-X2 direction, and the second groove 52 extends in parallel to the Y1-Y2 direction. The first groove 51 is provided in the vicinity of the center of the higher-order topological insulator layer 20 in the Y1-Y2 direction and extends from an end on the X2 side of the higher-order topological insulator layer 20 to the center in the X1-X2 direction. The third groove 53 is provided in the vicinity of the center of the higher-order topological insulator layer 20 in the Y1-Y2 direction and extends from an end on the X1 side of the higher-order topological insulator layer 20 to the center in the X1-X2 direction. Therefore, the first groove 51 and the third groove 53 are formed in a straight line. The second groove 52 is provided in the vicinity of the center of the higher-order topological insulator layer 20 in the X1-X2 direction and extends from an end on the Y1 side of the higher-order topological insulator layer 20 to the center in the Y1-Y2 direction. Therefore, the second groove 52 is orthogonal to the first groove 51 and the third groove 53.

The higher-order topological insulator layer 20 includes a first region 21 on the Y2 side of the first groove 51 and the third groove 53. The higher-order topological insulator layer 20 includes a second region 22 on the Y1 side of the first groove 51 and on the X2 side of the second groove 52. The higher-order topological insulator layer 20 includes a third region 23 on the Y1 side of the third groove 53 and on the X1 side of the second groove 52.

Each of the first region 21, the second region 22, and the third region 23 includes a hinge helical channel on one of two intersecting lines of a plane perpendicular to the a-axis direction and a plane perpendicular to the c-axis direction. The hinge helical channel is parallel to the b-axis direction. For example, the first region 21 includes a first hinge helical channel 11 on an intersecting line (ridge line) between a top surface and the side surface on the Y1 side. The second region 22 includes a second hinge helical channel 12 on an intersecting line between the side surface on the Y2 side and a bottom surface of the first groove 51. The third region 23 includes a third hinge helical channel 13 on an intersecting line between the side surface on the Y2 side and a bottom surface of the third groove 53. The first hinge helical channel 11 may be provided on an intersecting line between the side surface of the first region 21 on the Y1 side and a bottom surface of the groove 50, the second hinge helical channel 12 may be provided on an intersecting line between the top surface of the second region 22 and the side surface on the Y2 side, and the third hinge helical channel 13 may be provided on an intersecting line between the top surface of the third region 23 and the side surface on the Y2 side.

The first ferromagnetic insulator layer 31 is provided on the first region 21, the second region 22, and a part of the groove 50 and covers a part of the first hinge helical channel 11 and the second hinge helical channel 12. The second ferromagnetic insulator layer 32 is provided on the second region 22, the third region 23, and a part of the groove 50 and covers a part of the second hinge helical channel 12 and the third hinge helical channel 13. The third ferromagnetic insulator layer 33 is provided on the third region 23, the first region 21, and a part of the groove 50 and covers a part of the third hinge helical channel 13 and the first hinge helical channel 11. As a material of the first ferromagnetic insulator layer 31, the second ferromagnetic insulator layer 32, and the third ferromagnetic insulator layer 33, Cr₂Ga₂Te₆ is exemplified. The materials of the first ferromagnetic insulator layer 31, the second ferromagnetic insulator layer 32, and the third ferromagnetic insulator layer 33 may be other diluted magnetic semiconductors. A thickness of the first ferromagnetic insulator layer 31, the second ferromagnetic insulator layer 32, the third ferromagnetic insulator layer 33 is, for example, about 30 nm.

The second ferromagnetic insulator layer 32 is separated from the first ferromagnetic insulator layer 31 toward the X1 side on the second hinge helical channel 12, in the X1-X2 direction. The third ferromagnetic insulator layer 33 is separated from the second ferromagnetic insulator layer 32 toward the X1 side on the third hinge helical channel 13, in the X1-X2 direction. The third ferromagnetic insulator layer 33 is separated from the first ferromagnetic insulator layer 31 toward the X1 side on the first hinge helical channel 11, in the X1-X2 direction.

The first gate electrode 41 is provided on the first ferromagnetic insulator layer 31. The second gate electrode 42 is provided on the second ferromagnetic insulator layer 32. The third gate electrode 43 is provided on the third ferromagnetic insulator layer 33. As a material of the first gate electrode 41, the second gate electrode 42, and the third gate electrode 43, Au is exemplified. A thickness of the first gate electrode 41, the second gate electrode 42, and the third gate electrode 43 is, for example, about 100 nm.

The first SQUID 61 includes a lower superconductor layer 61A, a lower superconductor layer 61B, a tunnel barrier layer 61C, and an upper superconductor layer 61D.

The lower superconductor layers 61A and 61B protrude toward the X2 side from the side surface of the s-wave superconductor layer 10 on the X2 side. The lower superconductor layer 61A is provided on the Y2 side of the lower superconductor layer 61B. In planar view, the lower superconductor layer 61A protrudes toward the X2 side from the first region 21, and the lower superconductor layer 61B protrudes toward the X2 side from the second region 22. The lower superconductor layers 61A and 61B are formed integrally with the s-wave superconductor layer 10 from the material same as that of the s-wave superconductor layer 10. The lower superconductor layers 61A and 61B are connected to the s-wave superconductor layer 10. The lower superconductor layers 61A and 61B are, for example, Nb layers having a thickness of about 100 nm to 200 nm.

The tunnel barrier layer 61C and the upper superconductor layer 61D have a U-shaped planar shape. As a material of the tunnel barrier layer 61C, NbOₓ is exemplified, and as a material of the upper superconductor layer 61D, Nb is exemplified. A thickness of the tunnel barrier layer 61C is, for example, about 1 nm to 5 nm, and a thickness of the upper superconductor layer 61D is, for example, about 100 nm to 200 nm. One end of the tunnel barrier layer 61C has contact with the lower superconductor layer 61A, and another end has contact with the lower superconductor layer 61B. The upper superconductor layer 61D is provided on the tunnel barrier layer 61C.

The tunnel barrier layer 61C is sandwiched between the lower superconductor layer 61A and the upper superconductor layer 61D and between the lower superconductor layer 61B and the upper superconductor layer 61D. The first SQUID 61 is configured by such Josephson junction. The first SQUID 61 detects a change in a magnetic flux between the first hinge helical channel 11 and the second hinge helical channel 12.

The second SQUID 62 includes a lower superconductor layer 62A, a lower superconductor layer 62B, a tunnel barrier layer 62C, and an upper superconductor layer 62D.

The lower superconductor layers 62A and 62B protrude toward the Y1 side from the side surface of the s-wave superconductor layer 10 on the Y1 side. The lower superconductor layer 62A is provided on the X2 side of the lower superconductor layer 62B. In planar view, the lower superconductor layer 62A protrudes toward the Y1 side from the second region 22, and the lower superconductor layer 62B protrudes toward the Y1 side from the third region 23. The lower superconductor layers 62A and 62B are formed integrally with the s-wave superconductor layer 10 from the material same as that of the s-wave superconductor layer 10. The lower superconductor layers 62A and 62B are connected to the s-wave superconductor layer 10. The lower superconductor layers 62A and 62B are, for example, Nb layers having a thickness of about 100 nm to 200 nm.

The tunnel barrier layer 62C and the upper superconductor layer 62D have a U-shaped planar shape. As a material of the tunnel barrier layer 62C, NbOₓ is exemplified, and as a material of the upper superconductor layer 62D, Nb is exemplified. A thickness of the tunnel barrier layer 62C is, for example, about 1 nm to 5 nm, and a thickness of the upper superconductor layer 62D is, for example, about 100 nm to 200 nm. One end of the tunnel barrier layer 62C has contact with the lower superconductor layer 62A, and another end has contact with the lower superconductor layer 62B. The upper superconductor layer 62D is provided on the tunnel barrier layer 62C.

The tunnel barrier layer 62C is sandwiched between the lower superconductor layer 62A and the upper superconductor layer 62D and between the lower superconductor layer 62B and the upper superconductor layer 62D. The second SQUID 62 is configured by such Josephson junction. The second SQUID 62 detects a change in a magnetic flux between the second hinge helical channel 12 and the third hinge helical channel 13.

The third SQUID 63 includes a lower superconductor layer 63A, a lower superconductor layer 63B, a tunnel barrier layer 63C, and an upper superconductor layer 63D.

The lower superconductor layers 63A and 63B protrude toward the X1 side from the side surface of the s-wave superconductor layer 10 on the X1 side. The lower superconductor layer 63A is provided on the Y1 side of the lower superconductor layer 63B. In planar view, the lower superconductor layer 63A protrudes toward the X1 side from the third region 23, and the lower superconductor layer 63B protrudes toward the X1 side from the first region 21. The lower superconductor layers 63A and 63B are formed integrally with the s-wave superconductor layer 10 from the material same as that of the s-wave superconductor layer 10. The lower superconductor layers 63A and 63B are connected to the s-wave superconductor layer 10. The lower superconductor layers 63A and 63B are, for example, Nb layers having a thickness of about 100 nm to 200 nm.

The tunnel barrier layer 63C and the upper superconductor layer 63D have a U-shaped planar shape. As a material of the tunnel barrier layer 63C, NbOₓ is exemplified, and as a material of the upper superconductor layer 63D, Nb is exemplified. A thickness of the tunnel barrier layer 63C is, for example, about 1 nm to 5 nm, and a thickness of the upper superconductor layer 63D is, for example, about 100 nm to 200 nm. One end of the tunnel barrier layer 63C has contact with the lower superconductor layer 63A, and another end has contact with the lower superconductor layer 63B. The upper superconductor layer 63D is provided on the tunnel barrier layer 63C.

The tunnel barrier layer 63C is sandwiched between the lower superconductor layer 63A and the upper superconductor layer 63D and between the lower superconductor layer 63B and the upper superconductor layer 63D. The third SQUID 63 is configured by such Josephson junction. The third SQUID 63 detects a change in a magnetic flux between the third hinge helical channel 13 and the first hinge helical channel 11.

In the quantum bit 1 configured in this way, four Majorana particles γ1, γ2, γ3, and γ4 are expressed. For example, the Majorana particle γ1 is stably expressed in the vicinity of the first gate electrode 41 of the first hinge helical channel 11, and the Majorana particle γ4 is stably expressed in the vicinity of the third gate electrode 43 of the first hinge helical channel 11. Furthermore, for example, the Majorana particle γ2 is stably expressed between the first gate electrode 41 and the second gate electrode 42 of the second hinge helical channel 12, and the Majorana particle γ3 is stably expressed between the second gate electrode 42 and the third gate electrode 43 of the third hinge helical channel 13. Then, exchange of the Majorana particles γ1 to γ4 is performed by a change in an electrostatic potential caused by application of a gate voltage to the first gate electrode 41, the second gate electrode 42, and the third gate electrode 43.

For example, in the exchange of the Majorana particles γ1 and γ2, an electric field is applied from the first gate electrode 41, and a minute change in the magnetic flux at the time of the exchange of the Majorana particles γ1 and γ2 is detected as a minute change in a voltage signal by the first SQUID 61. In the exchange of the Majorana particles γ2 and γ3, an electric field is applied from the second gate electrode 42, and a minute change in the magnetic flux at the time of the exchange of the Majorana particles γ2 and γ3 is detected as a minute change in a voltage signal by the second SQUID 62. Furthermore, in the exchange of the Majorana particles γ3 and γ4, an electric field is applied from the third gate electrode 43, and a minute change in the magnetic flux at the time of the exchange of the Majorana particles γ3 and γ4 is detected as a minute change in a voltage signal by the third SQUID 63.

A single-layer film of WTe₂ that is a layered material of transition metal dichalcogenide is easily oxidized, and properties change when exposed to the atmosphere. By sandwiching the single-layer film of WTe₂ with chemically stable substances such as hexagonal boron nitride (h-BN) or graphene, it is possible to prevent oxidation. However, in that case, a process for manufacturing the quantum bit is complicated. Furthermore, it is difficult to adjust a size of the single-layer film of WTe₂. On the other hand, in the present embodiment, since the higher-order topological insulator layer 20 such as the multilayer WTe₂ is used, a configuration for preventing the oxidation is not needed. Furthermore, the adjustment of the size of the higher-order topological insulator layer 20 is easier than the adjustment of the size of the single-layer film of WTe₂.

Furthermore, it is possible to provide the plurality of quantum bits 1 on the substrate 90 to perform multi-quantization or to implement a semiconductor integrated circuit on the substrate 90. Therefore, according to the present embodiment, it is possible to accelerate research and development for realizing a practical error resistant quantum computer.

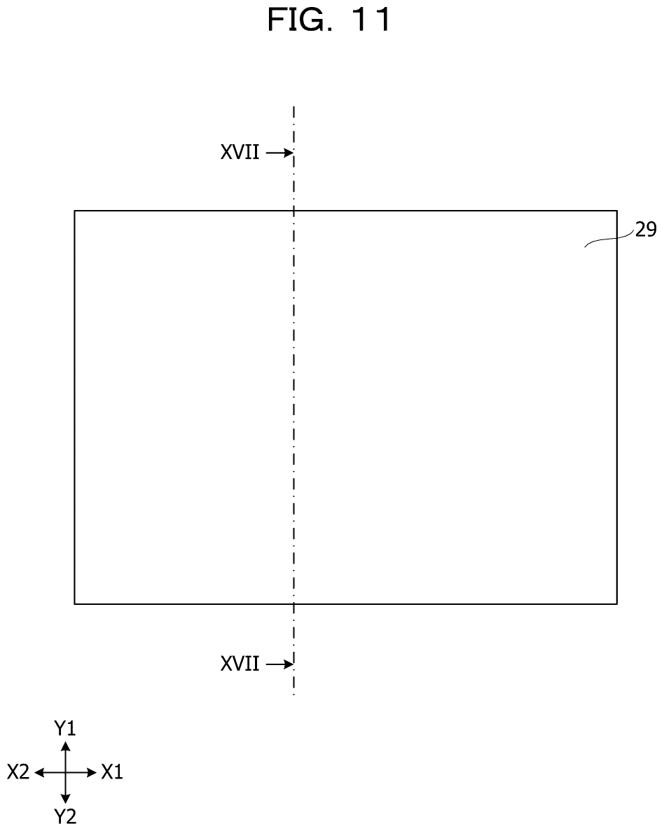

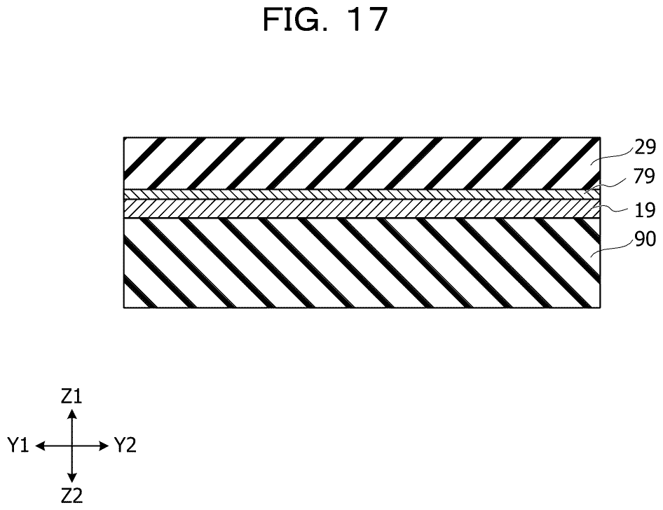

Next, a method for manufacturing the quantum bit 1 according to the fourth embodiment will be described. FIGS. 11 to 16 are top views illustrating the method for manufacturing the quantum bit 1 according to the fourth embodiment. FIGS. 17 to 22 are cross-sectional views illustrating the method for manufacturing the quantum bit 1 according to the fourth embodiment.

First, as illustrated in FIGS. 11 to 17, the substrate 90 is prepared, and annealing processing on the substrate 90 is executed for 3 hours to 4 hours at about 1200° C., under an oxygen atmosphere at atmospheric pressure. Next, the substrate 90 is immersed in methanol for 20 minutes to 30 minutes, and rinse processing is executed with ultrapure water. By these processing, it is possible to improve flatness of the surface of the substrate 90. FIG. 17 corresponds to a cross-sectional view taken along a XVII-XVII line in FIG. 11.

Thereafter, an s-wave superconductor layer 19 is formed on the substrate 90, a Te layer 79 is formed on the s-wave superconductor layer 19, and a higher-order topological insulator layer 29 is formed on the Te layer 79. Hereinafter, description will be made as assuming that an Nb layer is formed as the s-wave superconductor layer 19 and a multilayer WTe₂ is formed as the higher-order topological insulator layer 29. The s-wave superconductor layer 19, the Te layer 79, and the higher-order topological insulator layer 29 can be epitaxially grown in situ in the same vacuum chamber, for example, by the PLD method. A basic vacuum at the time when the s-wave superconductor layer 19, the Te layer 79, and the higher-order topological insulator layer 29 are formed is set to, for example, equal to or less than 5×10⁻⁶ Pa. When the s-wave superconductor layer 19, the Te layer 79, and the higher-order topological insulator layer 29 are formed by the PLD method, a KrF excimer laser (λ=248 nm) light source can be used as a laser light source. Note that a method for forming the s-wave superconductor layer 19, the Te layer 79, and the higher-order topological insulator layer 29 is not limited to the PLD method. For example, the s-wave superconductor layer 19, the Te layer 79, and the higher-order topological insulator layer 29 may be formed by a sputtering method, the s-wave superconductor layer 19 and the Te layer 79 may be formed by a vapor deposition method, and the higher-order topological insulator layer 29 may be formed by a co-vapor deposition method. In this way, the s-wave superconductor layer 19, the Te layer 79, and the higher-order topological insulator layer 29 can be formed by a physical vapor deposition method in a vacuum in-situ process.

In a case where the Nb layer is formed as the s-wave superconductor layer 19 by the PLD method, for example, an Nb pure metal target can be used as a target. When the s-wave superconductor layer 19 is formed, for example, a temperature of the substrate 90 is held at about 400° C., a laser energy density is set to 2.0 J/cm² to 5.0 J/cm², an irradiation frequency is set to 10 Hz, a distance between the substrate 90 and the target is set to about 5 cm, and a film formation rate is set to 0.5 nm/minute to 1.0 nm/minute. On the substrate 90 held at about 400° C., the Nb layer is epitaxially grown while being oriented in a direction.

When the Te layer 79 is formed, for example, a Te pure metal target can be used as a target. When the Te layer 79 is formed, for example, the temperature of the substrate 90 is held at about 200° C., the laser energy density is set to 1.0 J/cm² to 2.0 J/cm², the irradiation frequency is set to 1 Hz, the distance between the substrate 90 and the target is set to about 5 cm, and the film formation rate is set to 0.5 nm/minute to 1.5 nm/minute.

When the multilayer WTe₂ is formed as the higher-order topological insulator layer 29 by the PLD method, for example, a WTe₂ sintered body target can be used as a target. When the higher-order topological insulator layer 29 is formed, for example, the temperature of the substrate 90 is held at about 325° C., the laser energy density is set to 1.0 J/cm² to 2.0 J/cm², the irradiation frequency is set to 10 Hz, the distance between the substrate 90 and the target is set to about 5 cm, and the film formation rate is set to 0.5 nm/minute to 1.5 nm/minute. The higher-order topological insulator layer 29 (multilayer WTe₂) is oriented in the c-axis direction on the s-wave superconductor layer 19 (Nb layer), and a crystal structure of the higher-order topological insulator layer 29 indicates a Ta structure.

Note that, after the multilayer WTe₂ is formed, it is preferable to perform post annealing for 30 minutes to 1 hour at about 300° C. This is because the crystallinity of the multilayer WTe₂ is improved.

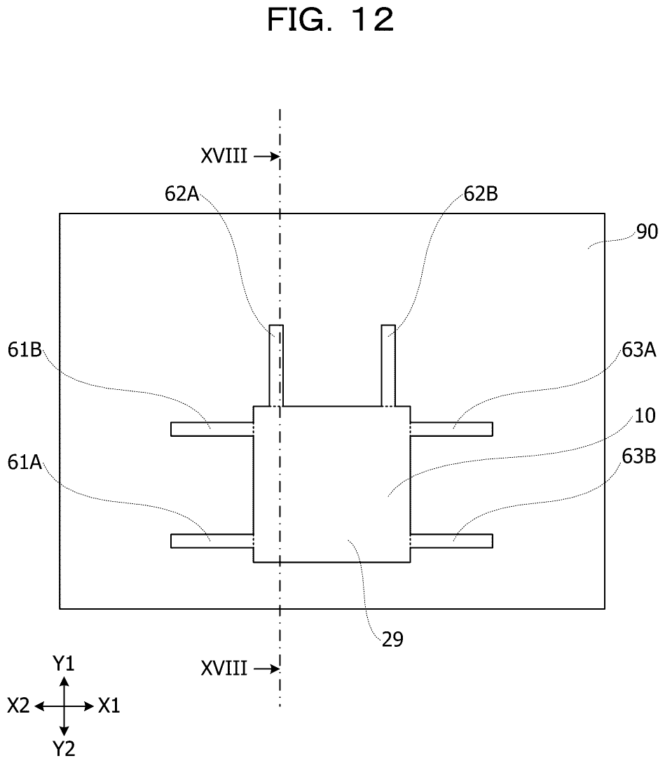

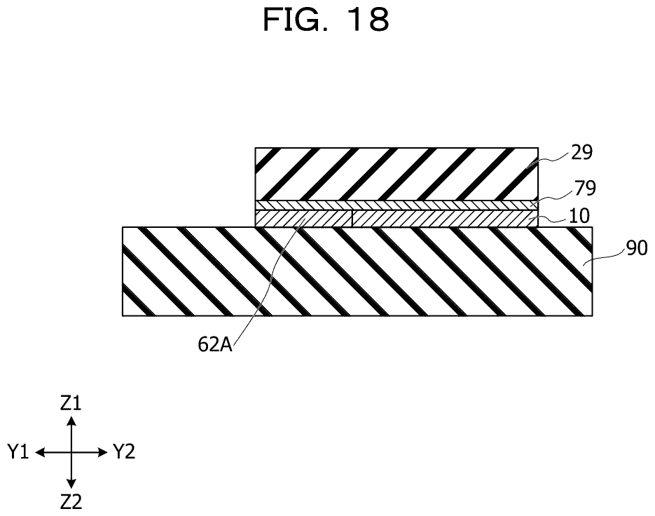

After the formation of the higher-order topological insulator layer 29, as illustrated in FIGS. 12 and 18, the s-wave superconductor layer 19, the Te layer 79, and the higher-order topological insulator layer 29 are processed, and the s-wave superconductor layer 10, the lower superconductor layer 61A, the lower superconductor layer 61B, the lower superconductor layer 62A, the lower superconductor layer 62B, the lower superconductor layer 63A, and the lower superconductor layer 63B are formed from the s-wave superconductor layer 19. FIG. 18 corresponds to a cross-sectional view taken along a XVIII-XVIII line in FIG. 12.

When the s-wave superconductor layer 19, the Te layer 79, and the higher-order topological insulator layer 29 are processed, first, a first electron beam resist is spin coated on the higher-order topological insulator layer 29. Next, a first mask pattern is formed from the first electron beam resist by electron beam lithography. The first mask pattern covers portions of the s-wave superconductor layer 19 where the s-wave superconductor layer 10, the lower superconductor layer 61A, the lower superconductor layer 61B, the lower superconductor layer 62A, the lower superconductor layer 62B, the lower superconductor layer 63A, and the lower superconductor layer 63B are to be formed from above the higher-order topological insulator layer 29 and exposes other portions. As the first electron beam resist, for example, a resist obtained by diluting ZEP 520A (manufactured by ZEON CORPORATION.) with ZEP-A (manufactured by ZEON CORPORATION.) at 1:1 can be used. After the formation of the first mask pattern, the s-wave superconductor layer 19, the Te layer 79, and the higher-order topological insulator layer 29 are processed by Ar ion milling. In the Ar ion milling, for example, a beam acceleration voltage is set to 280 V, and a beam current is set to 150 mA.

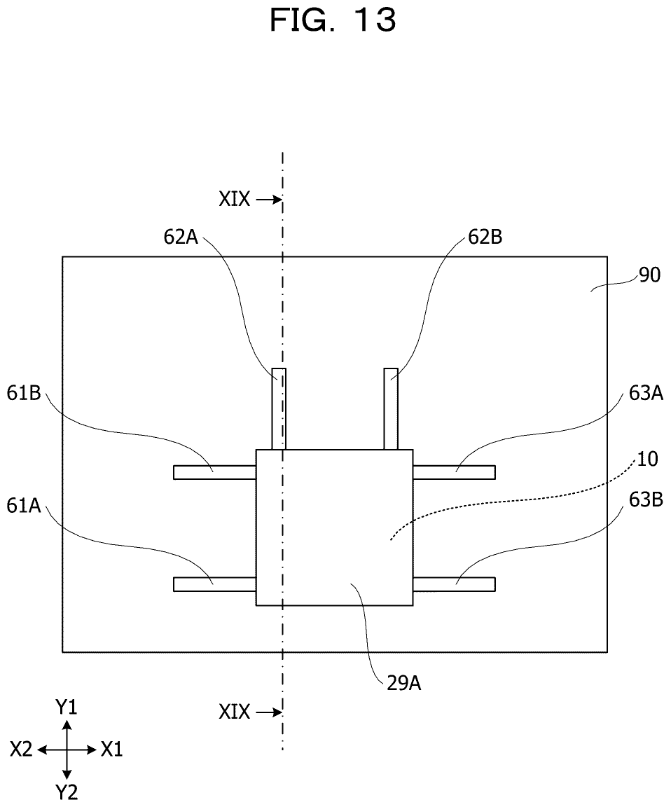

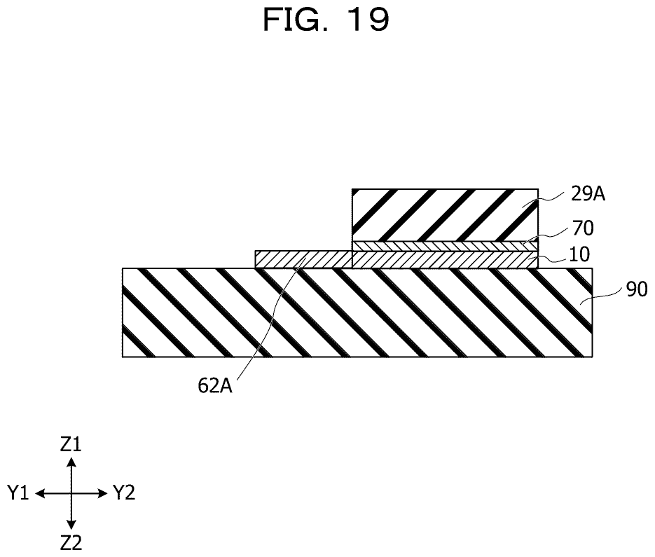

After the s-wave superconductor layer 19, the Te layer 79, and the higher-order topological insulator layer 29 are processed, the first mask pattern is removed, as illustrated in FIGS. 13 and 19, the higher-order topological insulator layer 29 and the Te layer 79 are processed, a higher-order topological insulator layer 29A having a rectangular planar shape and a flat top surface is formed from the higher-order topological insulator layer 29, and the Te layer 70 having a rectangular planar shape is formed from the Te layer 79. FIG. 19 corresponds to a cross-sectional view taken along a XIX-XIX line in FIG. 13.

When the higher-order topological insulator layer 29 and the Te layer 79 are processed, first, a second electron beam resist is spin coated on the higher-order topological insulator layer 29 and the substrate 90. Next, a second mask pattern is formed from the second electron beam resist by the electron beam lithography. The second mask pattern covers a portion of the higher-order topological insulator layer 29 on the s-wave superconductor layer 10 and exposes portions of the higher-order topological insulator layer 29 on the lower superconductor layer 61A, the lower superconductor layer 61B, the lower superconductor layer 62A, the lower superconductor layer 62B, the lower superconductor layer 63A, and the lower superconductor layer 63B. As the second electron beam resist, for example, a resist obtained by diluting ZEP 520A (manufactured by ZEON CORPORATION.) with ZEP-A (manufactured by ZEON CORPORATION.) at 1:1 can be used. After the formation of the second mask pattern, the higher-order topological insulator layer 29 and the Te layer 79 are processed by the Ar ion milling. As a result, the higher-order topological insulator layer 29A and the Te layer 70 are formed, and the lower superconductor layer 61A, the lower superconductor layer 61B, the lower superconductor layer 62A, the lower superconductor layer 62B, the lower superconductor layer 63A, and the lower superconductor layer 63B are exposed from the higher-order topological insulator layer 29A and the Te layer 70. In the Ar ion milling, for example, the beam acceleration voltage is set to 280 V, and the beam current is set to 150 mA.

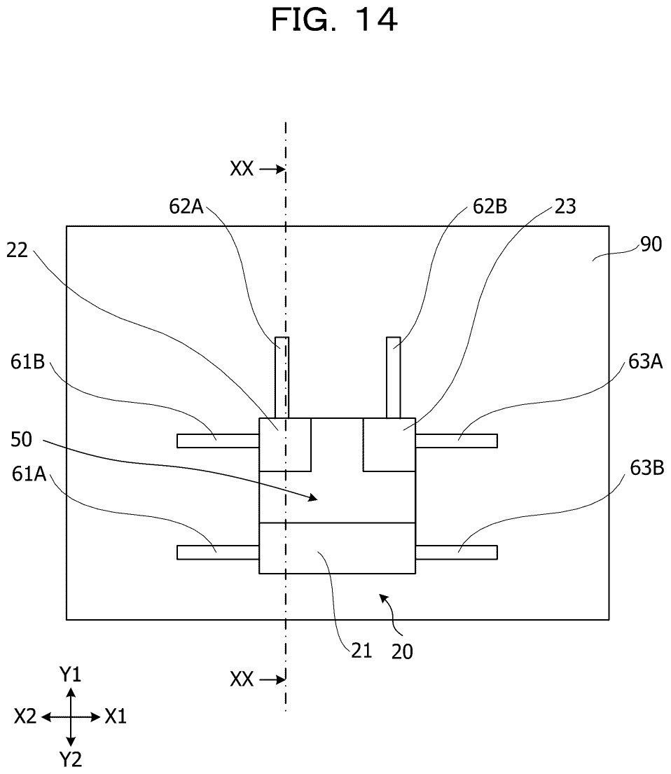

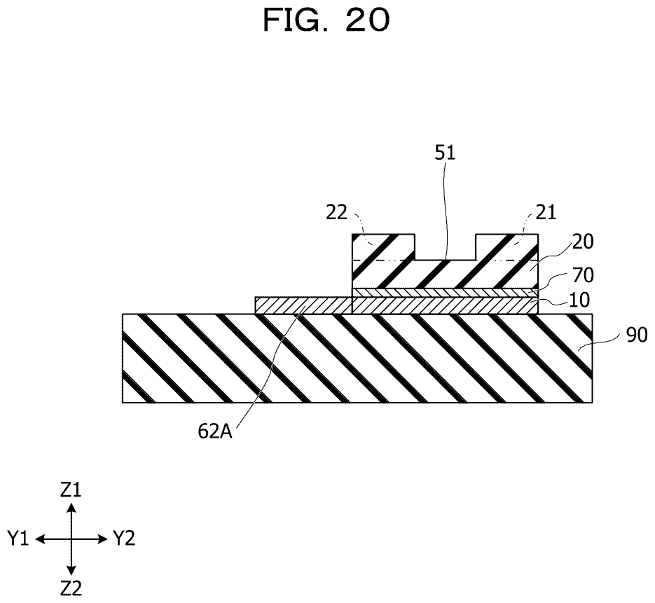

After the higher-order topological insulator layer 29A and the Te layer 70 are formed, the second mask pattern is removed, as illustrated in FIGS. 14 and 20, the higher-order topological insulator layer 29A is processed, and the higher-order topological insulator layer 20 including the first region 21, the second region 22, and the third region 23 is formed from the higher-order topological insulator layer 29A. FIG. 20 corresponds to a cross-sectional view taken along a XX-XX line in FIG. 14.

When the higher-order topological insulator layer 29A is processed, first, a third electron beam resist is spin coated on the higher-order topological insulator layer 29A, the substrate 90, the lower superconductor layer 61A, the lower superconductor layer 61B, the lower superconductor layer 62A, the lower superconductor layer 62B, the lower superconductor layer 63A, and the lower superconductor layer 63B. Next, a third mask pattern is formed from the third electron beam resist by the electron beam lithography. The third mask pattern exposes a portion of the higher-order topological insulator layer 29A where the groove 50 is to be formed and covers other portions. As the third electron beam resist, for example, a resist obtained by diluting ZEP 520A (manufactured by ZEON CORPORATION.) with ZEP-A (manufactured by ZEON CORPORATION.) at 1:1 can be used. After the formation of the third mask pattern, the higher-order topological insulator layer 29A is processed by the Ar ion milling. As a result, the groove 50 including the first groove 51, the second groove 52, and the third groove 53 is formed, and the higher-order topological insulator layer 20 including the first region 21, the second region 22, and the third region 23 is obtained. The first region 21 includes the first hinge helical channel 11, the second region 22 includes the second hinge helical channel 12, and the third region 23 includes the third hinge helical channel 13 (refer to FIG. 10). In the Ar ion milling, for example, the beam acceleration voltage is set to 280 V, and the beam current is set to 150 mA.

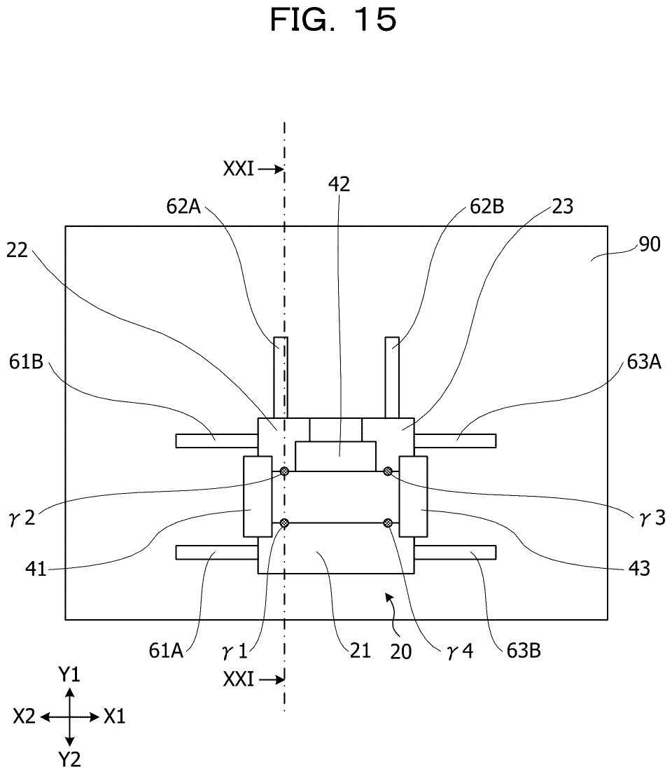

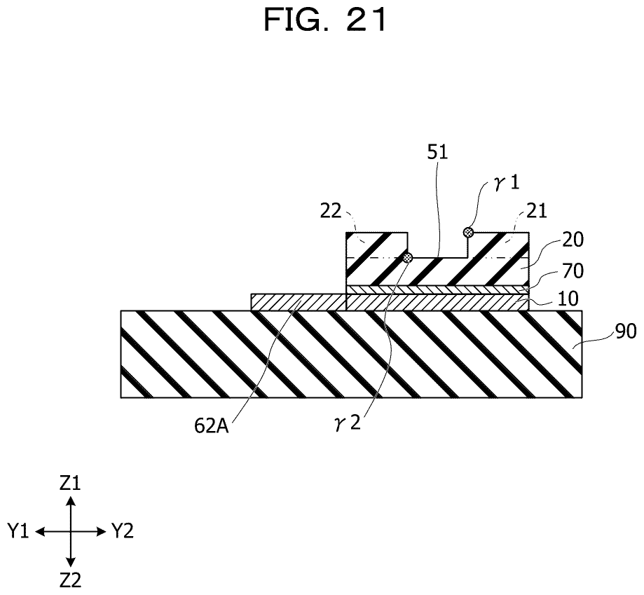

After the formation of the higher-order topological insulator layer 20, the third mask pattern is removed, as illustrated in FIGS. 15 and 21, the first ferromagnetic insulator layer 31, the second ferromagnetic insulator layer 32, the third ferromagnetic insulator layer 33, the first gate electrode 41, the second gate electrode 42, and the third gate electrode 43 are formed. FIG. 21 corresponds to a cross-sectional view taken along a XXI-XXI line in FIG. 15.

When the first ferromagnetic insulator layer 31, the second ferromagnetic insulator layer 32, the third ferromagnetic insulator layer 33, the first gate electrode 41, the second gate electrode 42, and the third gate electrode 43 are formed, first, a fourth electron beam resist is spin coated on the higher-order topological insulator layer 20, the substrate 90, the lower superconductor layer 61A, the lower superconductor layer 61B, the lower superconductor layer 62A, the lower superconductor layer 62B, the lower superconductor layer 63A, and the lower superconductor layer 63B. Next, a fourth mask pattern is formed from the fourth electron beam resist by the electron beam lithography. The fourth mask pattern exposes portions where the first ferromagnetic insulator layer 31, the second ferromagnetic insulator layer 32, the third ferromagnetic insulator layer 33, the first gate electrode 41, the second gate electrode 42, and the third gate electrode 43 are to be formed and covers other portions. As the fourth electron beam resist, for example, a resist obtained by diluting ZEP 520A (manufactured by ZEON CORPORATION.) with ZEP-A (manufactured by ZEON CORPORATION.) at 1:1 can be used. After the formation of the fourth mask pattern, a Cr₂Ga₂Te₆ layer and an Au layer are formed by the PLD method.

When the Cr₂Ga₂Te₆ layer is formed by the PLD method, for example, the temperature of the substrate 90 is held at about 200° C., the laser energy density is set to 1.0 J/cm² to 2.0 J/cm², the irradiation frequency is set to 1 Hz, the distance between the substrate 90 and the target is set to about 5 cm, and the film formation rate is set to 1.0 nm/minute to 2.0 nm/minute.

When the Au layer is formed by the PLD method, for example, the temperature of the substrate 90 is held at a room temperature, the laser energy density is set to 1.0 J/cm² to 2.0 J/cm², the irradiation frequency is set to 5 Hz, the distance between the substrate 90 and the target is set to about 5 cm, and the film formation rate is set to 5.0 nm/minute to 10.0 nm/minute.

After the formation of the Cr₂Ga₂Te₆ layer and the Au layer, the fourth mask pattern is removed together with the Cr₂Ga₂Te₆ layer and the Au layer deposited thereon. For example, lift-off is performed. As a result, the first ferromagnetic insulator layer 31, the second ferromagnetic insulator layer 32, the third ferromagnetic insulator layer 33, the first gate electrode 41, the second gate electrode 42, and the third gate electrode 43 are obtained. Furthermore, the four Majorana particles γ1, γ2, γ3, and γ4 are expressed.

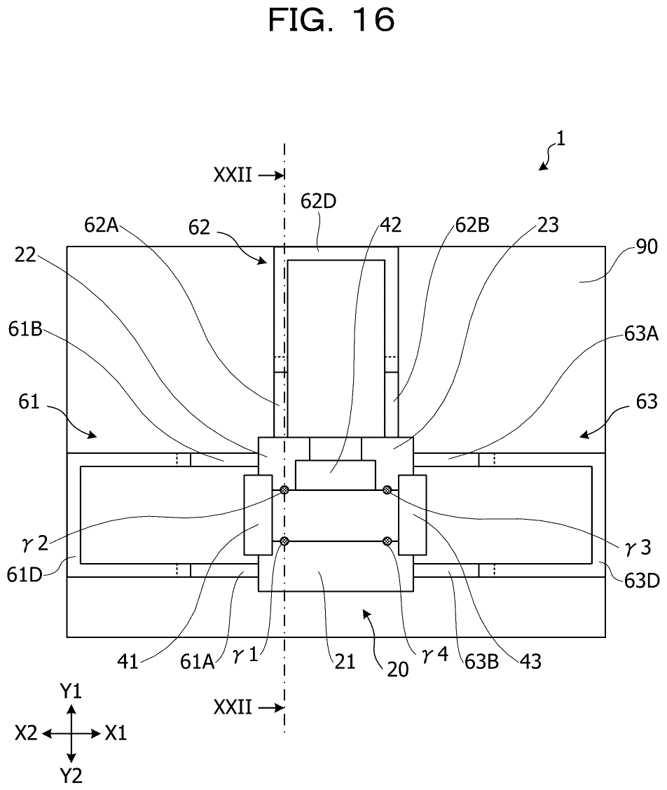

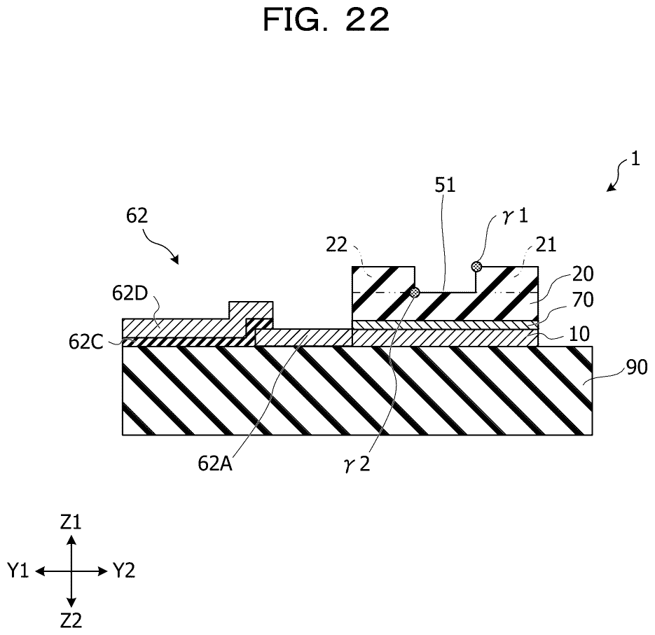

Next, as illustrated in FIGS. 16 and 22, the tunnel barrier layers 61C to 63C and the upper superconductor layers 61D to 63D are formed. FIG. 22 corresponds to a cross-sectional view taken along a XXII-XXII line in FIG. 16.

When the tunnel barrier layers 61C to 63C and the upper superconductor layers 61D to 63D are formed, first, a fifth electron beam resist is spin coated on the higher-order topological insulator layer 20, the substrate 90, the lower superconductor layer 61A, the lower superconductor layer 61B, the lower superconductor layer 62A, the lower superconductor layer 62B, the lower superconductor layer 63A, the lower superconductor layer 63B, the first gate electrode 41, the second gate electrode 42, and the third gate electrode 43. Next, a fifth mask pattern is formed from the fifth electron beam resist by the electron beam lithography. The fifth mask pattern exposes portions where the tunnel barrier layers 61C to 63C and the upper superconductor layers 61D to 63D are to be formed and covers other portions. As the fifth electron beam resist, for example, a resist obtained by diluting ZEP 520A (manufactured by ZEON CORPORATION.) with ZEP-A manufactured by ZEON CORPORATION.) at 1:1 can be used. After the formation of the fifth mask pattern, an NbOₓ layer and an Nb layer are formed by the PLD method.

When the NbOₓ layer is formed by the PLD method, for example, a target of an Nb metal is used, the temperature of the substrate 90 is held at a room temperature, and an oxygen partial pressure of the vacuum chamber is adjusted to about 50 Pa to 55 Pa. The Nb layer can be formed under conditions similar to those of the s-wave superconductor layer 19.

After the formation of the NbOₓ layer and the Nb layer, the fifth mask pattern is removed together with the NbOₓ layer and the Nb layer deposited thereon. For example, lift-off is performed. As a result, the tunnel barrier layers 61C to 63C and the upper superconductor layers 61D to 63D are obtained, and the first SQUID 61, the second SQUID 62, and the third SQUID 63 are formed.

In this way, the quantum bit 1 according to the fourth embodiment can be manufactured.

The material of the higher-order topological insulator layer 20 is not limited to the multilayer WTe₂. The higher-order topological insulator layer 20 may include Mo, Nb, W, Ta, Ti, Zr, Fe, Pd, Ir, or Pt, or any combination thereof as a transition metal. Furthermore, the material of the s-wave superconductor layer 10 is not limited to Nb and may be, for example, Al or Pd.

A thickness of the Te layer 70 is preferably 1 nm to 20 nm, more preferably, 2 nm to 15 nm, and further more preferably, 3 nm to 10 nm. When the thickness of the Te layer 70 is excessive, there is a possibility that a proximity effect of superconduction by the s-wave superconductor layer is lowered.

### Fifth Embodiment

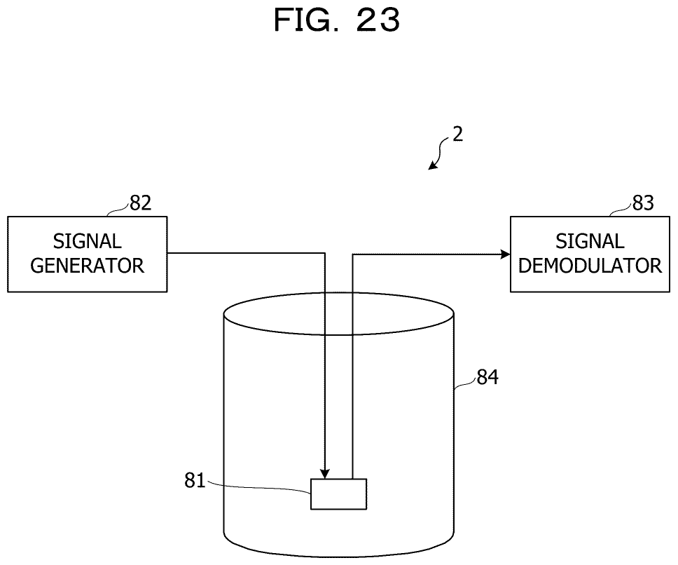

Next, a fifth embodiment will be described. A fifth embodiment relates to a quantum operation device including the quantum bit 1 according to the fourth embodiment. FIG. 23 is a diagram illustrating the quantum operation device according to the fifth embodiment.

A quantum operation device 2 according to the fifth embodiment includes a quantum bit chip 81, a signal generator 82, a signal demodulator 83, and a cryogenic dilution refrigerator 84, as illustrated in FIG. 23. The quantum bit chip 81 includes the plurality of quantum bits 1 according to the fourth embodiment. The quantum bit chip 81 is housed in the cryogenic dilution refrigerator 84 and is cooled to a temperature equal to or lower than 10 mK. The signal generator 82 generates a microwave pulse signal, and the microwave pulse signal is input to the quantum bit chip 81. The quantum bit chip 81 outputs a signal according to the microwave pulse signal, and the signal demodulator 83 demodulates the signal output from the quantum bit chip 81. The signal generator 82 and the signal demodulator 83 are used, for example, at a temperature of about room temperature.

Since the quantum operation device 2 according to the fifth embodiment includes the quantum bit 1 according to the fourth embodiment, the Majorana particles can be stably expressed, and operations can be stably performed.

Although the preferred embodiments and the like have been described in detail above, the present disclosure is not limited to the embodiments and the like described above, and various modifications and substitutions may be made to the embodiments and the like described above without departing from the scope described in claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A structure comprising:
a base material;
a first layer provided over the base material; and
a second layer provided over the first layer, wherein
the first layer is a Te layer, and
the second layer includes a transition metal ditelluride layer.

2. The structure according to claim 1, wherein the transition metal ditelluride layer includes Mo, Nb, W, Ta, Ti, Zr, Fe, Pd, Ir, or Pt, or any combination of Mo, Nb, W, Ta, Ti, Zr, Fe, Pd, Ir, or Pt.

3. The structure according to claim 1, wherein the second layer is a higher-order topological insulator layer that includes a plurality of the transition metal ditelluride layers laminated on the first layer.

4. The structure according to claim 1, wherein the base material includes an s-wave superconductor layer, and
the first layer is provided over the s-wave superconductor layer.

5. The structure according to claim 4, wherein the s-wave superconductor layer includes Nb, Al, or Pd.

6. The structure according to claim 1, wherein a thickness of the first layer is 1 nm to 20 nm.

7. A quantum bit comprising:
an s-wave superconductor layer;
a Te layer provided on the s-wave superconductor layer;
a higher-order topological insulator layer provided over the Te layer;
a first ferromagnetic insulator layer provided over the higher-order topological insulator layer; and
a first gate electrode provided over the first ferromagnetic insulator layer, wherein
the higher-order topological insulator layer includes
a first region that includes a first hinge helical channel, and
a second region that includes a second hinge helical channel separated from the first hinge helical channel, and
the first ferromagnetic insulator layer covers the first hinge helical channel and the second hinge helical channel.

8. The quantum bit according to claim 7, comprising: a first superconducting quantum interference device configured to detect a change in a magnetic flux between the first hinge helical channel and the second hinge helical channel.

9. The quantum bit according to claim 7, wherein
the higher-order topological insulator layer includes a third region that includes a third hinge helical channel separated from the first hinge helical channel and the second hinge helical channel, and
the quantum bit further comprises:
a second ferromagnetic insulator layer configured to cover the second hinge helical channel and the third hinge helical channel;
a second gate electrode provided over the second ferromagnetic insulator layer;
a third ferromagnetic insulator layer configured to cover the third hinge helical channel and the first hinge helical channel; and
a third gate electrode provided over the third ferromagnetic insulator layer.

10. The quantum bit according to claim 9, further comprising:
a second superconducting quantum interference device; and
a third superconducting quantum interference device, wherein
the second superconducting quantum interference device detects a change in a magnetic flux between the second hinge helical channel and the third hinge helical channel, and
the third superconducting quantum interference device detects a change in a magnetic flux between the third hinge helical channel and the first hinge helical channel.

11. The quantum bit according to claim 9, wherein
in the higher-order topological insulator layer,
a first groove that defines the first region and the second region,
a second groove that defines the second region and the third region, and
a third groove that defines the third region and the first region are formed.

12. The quantum bit according to claim 11, wherein
the first groove and the third groove extend in a common first direction,
the second groove extends in a second direction perpendicular to the first direction, and
the first groove, the second groove, and the third groove are connected.

13. The quantum bit according to claim 12, wherein the first groove, the second groove, and the third groove configure a T-shaped groove in planar view.

14. The quantum bit according to claim 7, wherein the higher-order topological insulator layer includes Mo, Nb, W, Ta, Ti, Zr, Fe, Pd, Ir, or Pt, or any combination of Mo, Nb, W, Ta, Ti, Zr, Fe, Pd, Ir, or Pt.

15. The quantum bit according to claim 7, wherein the s-wave superconductor layer includes Nb, Al, or Pd.

16. A method for manufacturing a structure, the method comprising:
forming a first layer over a base material; and
forming a second layer over the first layer, wherein
the first layer is a Te layer and
the second layer includes a transition metal ditelluride layer.

17. The method according to claim 16, wherein the first layer and the second layer are formed by a physical vapor deposition method in a vacuum in-situ process.
